(19) United States
(12) Patent Application Publication
(10) Pub. No.: US 2023/0045136 A1
(43) Pub. Date: Feb. 9, 2023

(54) STRUCTURED ASSEMBLY AND INTERCONNECT FOR PHOTOVOLTAIC SYSTEMS

(71) Applicant: mPower Technology, Inc., Albuquerque, NM (US)

(72) Inventor: Murat Okandan, Albuquerque, NM (US)

(73) Assignee: mPower Technology, Inc., Albuquerque, NM (US)

(21) Appl. No.: 17/793,846

(22) PCT Filed: Jan. 29, 2021
(86) PCT No.: PCT/US2021/015880

§ 371 Date: Jul. 19, 2022

Related U.S. Application Data
(60) Provisional application No. 62/967,498, filed on Jan. 29, 2020.

(51) Int. Cl. H01L 31/05; H01L 31/024; H01L 31/048; H01L 31/18; H02S 20/00

(52) U.S. Cl. CPC H01L 31/05; H01L 31/024; H01L 31/0481; H01L 31/18; H02S 20/00

(57) ABSTRACT

Structured photovoltaic assemblies and method of manufacture therefor. The assemblies can be assembled similar to flex circuits and have mechanical support structures disposed within the assembly. The supports can be sized and shaped to one or a group of solar cells in the assembly. The solar cells supported by a particular support may be interconnected with cells supported by a different support. The supports can be transparent. The connection of the interconnects to the solar cells can be enhanced by forming protrusions in vias through openings in the Insulating layer that are aligned with the solar cells. Alternatively, the openings can be filled with a conductive material in such forms as powder, ink, paste, or metal nanoparticles, and a laser can be used to melt and/or sinter the material to form the connection to the solar cell. These techniques can withstand large temperature swings over a large number of cycles, which occur in, for example, space applications.

### CROSS-REFERENCE TO RELATED APPLICATIONS

This application: claims priority to and the benefit of the filing of U.S. Provisional Patent No. 62/967,498 entitled “Structured Assembly and Interconnect for Photovoltaic Systems”, filed on Jan. 29, 2020, the specification and claims of which are incorporated herein by reference.

### BACKGROUND OF THE INVENTION

### Field of the Invention Technical Field

The present invention is related to fabrication, assembly, integration and operation of low cost, high performance solar energy systems and solar arrays with applications in aerospace, residential, commercial and industrial, remote power and utility scale solar power.

### BACKGROUND ART

Note that the following discussion may refer to a number of publications and references. Discussion of such publications herein is given for more complete background of the scientific principles and is not to be construed as an admission that such publications are prior art for patentability determination purposes.

Solar cells and associated components can be assembled using various shapes, interconnection methods and mechanical support structures to provide enhanced reliability and superior performance. While traditional assembly methods are quite effective with rigid glass/glass and glass/backsheet configurations, those systems do not accommodate flexing, dynamic loads and large number of rapid temperature cycles expected in a range of applications.

Conventional laser welding based on infrared (IR) laser sources are very commonly used in industry. However, these systems are not very suitable for creating precise connections between thin (several microns to a couple hundred microns thick) traces, for example in copper, and other layers in devices, for example, contacts in solar cells and/or other electronic devices. The energy deposited by the IR laser sources are quite high to produce initial melting of the metal, causing splatter patterns and voids in the melted metal and causing heating related damage in the materials surrounding the connection point. While laser operation can be quite fast (less than a second), movement of the work piece or the optical system makes this process fairly low throughput.

Parallel gap or pinch welding uses a mechanical contact between a tip (with two contact points) and the material(s) to be welded, and current that is forced between the tip causes the target material(s) to melt and be welded. This requires fairly large contact areas (500 μm and larger) coupled with significant amounts of energy deposition, which is hard to control and this can damage the materials adjacent to the connection point. Each connection process takes multiple seconds (up to 10 seconds if tip and work piece movement are included) and is not fast enough for high throughput manufacturing requirements.

Conventional photovoltaic assemblies use large solar cells (156 mm×156 mm and newer 210 mm×210 mm sizes) that are interconnected in series on large, rigid structures. While there are half-cut and third-cut cells starting to become available in the marketplace, these assemblies still do not provide the desired level of mechanical flexibility and resilience that enable rapid deployment, rapid recovery and reliable operation of solar systems.

### SUMMARY OF THE INVENTION DISCLOSURE OF THE INVENTION

An embodiment of the present invention is a photovoltaic assembly comprising a plurality of solar cells; interconnects for interconnecting the solar cells; and one or more mechanical support structures, the mechanical support structures each smaller than the photovoltaic assembly. The mechanical support structures preferably comprise various shapes and sizes. At least one support structure is optionally approximately the size and/or shape of a single solar cell or of a subset of the solar cells in the photovoltaic assembly. One or more solar cells in that subset of solar cells are optionally electrically interconnected to solar cells outside said subset of solar cells. Optionally, only some of the solar cells in that subset of solar cells are electrically interconnected with each other. Optionally at least one of the one or more mechanical support structures is transparent, optionally comprising a material selected from the group consisting of acrylic, glass, and polycarbonate. The assembly optionally comprises transparent mechanical support structures disposed in a direction relative to the solar cells from which the solar cells receive light. The one or more mechanical support structures are preferably oriented parallel to a plane of the solar cells. Optionally at least one mechanical support structure is embedded into a polymeric encapsulation layer, is disposed on a cell and interconnect assembly, the cell and interconnect assembly comprising a plurality of the solar cells and corresponding interconnects, is integrated into the cell and interconnect assembly, and/or is disposed in an insulating layer of the cell and interconnect assembly, in which case the mechanical support structure comprises a stamped fiberglass/polymer composite. The interconnects optionally comprise a plurality of interconnect vias through an insulating layer. Each via preferably comprises a protrusion to enhance contact with connection pads disposed on the solar cells. Interconnect traces are optionally shaped to reduce thermal stresses in the photovoltaic assembly, in which case the insulating layer between the interconnect traces and the solar cells comprises cutouts that at least partially approximately conform to the shaped interconnect traces.

Another embodiment of the present invention is a method of manufacturing a photovoltaic assembly, the method comprising providing a plurality of solar cells and interconnects and disposing one or more mechanical support structures in the photovoltaic assembly, the mechanical support structures each smaller than the photovoltaic assembly. The mechanical support structures preferably comprise various shapes and sizes. At least one support structure is optionally approximately the size and/or shape of a single solar cell or of a subset of the solar cells in the photovoltaic assembly. One or more solar cells in that subset of solar cells are optionally electrically interconnected to solar cells outside said subset of solar cells. Optionally, only some of the solar cells in that subset of solar cells are electrically interconnected with each other. Optionally at least one of the one or more mechanical support structures is transparent, optionally comprising a material selected from the group consisting of acrylic, glass, and polycarbonate. The method optionally comprises disposing transparent mechanical support structures in a direction relative to the solar cells from which the solar cells receive light. The method preferably comprises orienting the one or more mechanical support structures parallel to a plane of the solar cells. The method optionally comprises embedding at least one mechanical support structure into a polymeric encapsulation layer, disposing at least one mechanical support structure on a cell and interconnect assembly, the cell and interconnect assembly comprising a plurality of the solar cells and corresponding interconnects, integrating at least one mechanical support structure into the cell and interconnect assembly, and/or disposing the at least one mechanical support structure in an insulating layer of the cell and interconnect assembly.

The method optionally further comprises aligning a plurality of openings in the interconnects with connection pads disposed on the solar cells; depositing material in the openings; and using at least one laser beam to melt or sinter the material, thereby connecting the interconnects with the connection pads. The depositing step is preferably performed using inject printing, screen printing, or aerosol jet nozzle printing. The material preferably comprises powder, ink, paste, metal nanoparticles, copper, aluminum, transparent conductive oxides, indium tin oxide, polysilicon, silicided polysilicon, silver, titanium, or titanium-tungsten. The laser spot size is optionally smaller than a size of the openings, in which case the method preferably comprises scanning the laser beam within each opening. Alternatively, the laser spot size is approximately the same as a size of the openings. The laser color is preferably chosen to enhance laser absorption by the material.

The method optionally further comprises aligning interconnect vias through an insulating layer with connection pads disposed on the solar cells; and using at least one laser beam to melt the interconnect vias, thereby connecting the interconnects to the contact pads. The laser spot size is optionally smaller than a size of the openings, in which case the method preferably comprises scanning the laser beam within each opening. Alternatively, the laser spot size is approximately the same as a size of the openings. The laser color is preferably chosen to enhance laser absorption by the material.

The method of claim 20 comprising forming a protrusion on each of a plurality of interconnect vias through an insulating layer to enhance contact with connection pads disposed on the solar cells. The step of forming the protrusions is preferably performed by mechanically deforming the via with a pin, overplating the via, or double-screen printing a light curable conductive ink or paste layer.

The method optionally comprises shaping interconnect traces to reduce thermal stresses in the photovoltaic assembly, in which case the insulating layer between the interconnect traces and the solar cells preferably comprises cutouts that at least partially approximately conform to the shaped interconnect traces.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated into and form a part of the specification, illustrate the practice of embodiments of the present invention and, together with the description, serve to explain the principles of the invention. The drawings are only for the purpose of illustrating certain embodiments of the invention and are not to be construed as limiting the invention. In the figures:

FIGS. 1A and 1B show a flex circuit-like interconnect structure that is put in contact with the devices to be interconnected, such as solar cells, and a laser beam driven weld/connection being formed.

FIGS. 2A and 2B show an interconnection option where a flex circuit with openings in the interconnection region are put in contact with the devices to be connected, paste, ink or powder material is deposited, and contacts are formed using a laser driven sintering/melting/welding process.

FIGS. 3A-3C shows a structure for forming a bump in the copper interconnect region to produce close mechanical contact with the device before interconnect formation.

FIG. 4 shows a connection design where the embedded metal traces and/or insulating layers are shaped to provide mechanical relief to accommodate any movement and/or stress during the assembly process or during operation of the assembly.

FIGS. 5A-5D show a grouping of cells with mechanical support structures above, below, and both above and below, to provide mechanical resilience to the structure.

### DETAILED DESCRIPTION OF EMBODIMENTS OF THE INVENTION

Recent advances in short wavelength lasers (blue and green) have opened up new processing options in joining metals, either same type or dissimilar, metals and ceramics and polymers. Specific advantages have been provided in joining thin metal traces, such as 5 μm to 200 μm thick copper that can be found on flexible circuit-like assemblies, to components that need to be reliably attached and survive large temperature swings (for example, −100° C. to +100° C., or −200° C. to +200° C.) for a very large number of temperature cycles (50,000 or more). These advantages arise from the ability to deposit the desired amount of energy into the structures very quickly (on a milliseconds to 100 s of milliseconds timescale) based on enhanced absorption of blue and green light in these materials (for example, copper) and the ability to shape spot sizes of the laser beam being used for the process (for example, 10 s of microns to several hundred microns in diameter as a circle, or other shapes as needed). The controlled deposition of energy allows precise control of thermal effects around the desired welded connection, limiting or eliminating undesirable material changes in the assembly stack. Such undesirable changes could be intermixing of materials or thermal damage to layers adjacent to the connection point or mechanical or electrical disruption of the desired final structure.

In order to achieve higher throughput of processed material, it is possible to have multiple laser sources placed within the processing system, such that they can be operated in parallel on the same substrate/assembly or on multiple substrates/assemblies. While larger welding operations need hundreds of watts of power, the 10 s of microns to 100 s of microns lateral dimension weld spots in thinner layers could be generated with only 10 s of watts of power with the blue and green lasers. These lower power assemblies could be made with more compact semiconductor lasers and associated smaller scale optical components which can be placed directly on the structure that is moving inside the tool. Another possible arrangement is the coupling of these compact sources into fibers that are then attached to the moving segments within the tool.

In another embodiment, this approach also enables rapid sintering of metal powders or pastes that are deposited onto the interconnect regions. In this configuration, a hole in the copper trace allows the interconnect pad below to be accessible, and the material to be sintered/adhered is deposited onto that region using jet nozzle, inkjet printing or screen printing. Subsequently the laser beam heats, consolidates and/or melts the material that was deposited and forms the connection between the trace and the component below. The deposited material, for example could be pure copper or silver in nanoparticle form, with additives to provide desired chemical interactions within the deposited material and between the trace and the contact layer below. The contact layer below could also be copper, aluminum, transparent conductive oxides (such as indium-tin-oxide), polysilicon, silicided polysilicon, silver, titanium, titanium-tungsten or any suitable material stack for the interconnect. In case of Ti, Ti—W layers can also serve as adhesion and diffusion barrier layers where diffusion of certain elements is undesirable within the stack.

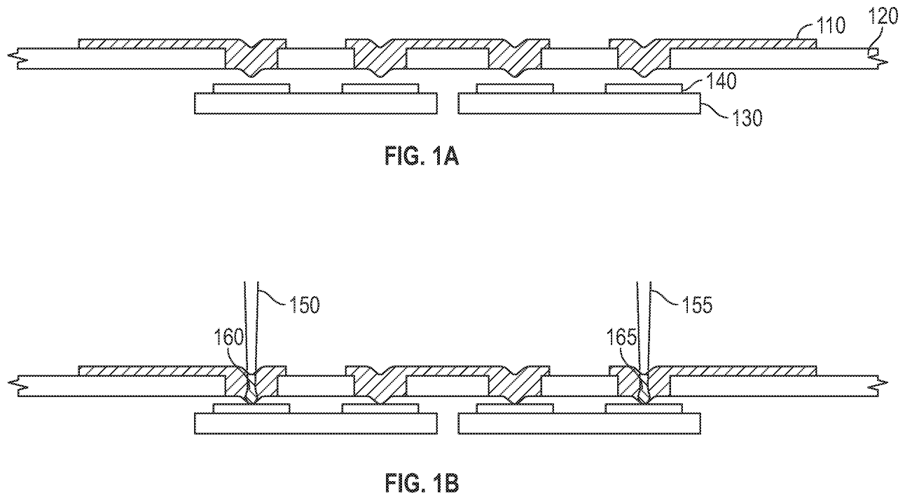

As shown in FIG. 1A, an interconnect structure, preferably formed using flex circuit-like processes or by lamination processes commonly in use in the terrestrial PV industry, comprising conductive layer 110 and insulating layer 120, comprising for example polyimide, is put in contact with solar cells 130. Conductive layer 110 may comprise copper that is electroplated or laminated onto the polyimide, or could be printed and sintered metal (silver, copper, aluminum, etc.). After cells and the interconnect structure are brought into contact, as shown in FIG. 1B, laser beams 150, 155 are used to join interconnect structure 110 with connection pads 140 that are on solar cells 130 or on other electrical/electronic components that are in the assembly, such as integrated circuits, capacitors, resistors, diodes, etc. The joining process is preferably performed by melting a substantial portion of the conductor in the interconnect onto to connection pads 140, or alternatively by melting multiple small regions (for example 10 s of μm to 100 μm) within the area of the connection pad and having multiple connection points per connection pad. Laser beams 150, 155 can be simultaneously used to perform multiple joining operations. Although the protrusions of conductive layer 110 extending downward toward connection pads 140 are shown as existing prior to laser melting, the may alternatively be formed at the same time as the laser process is being performed. This can be achieved by a laser head that comprises an integral tip or collet, or a separate mechanical feature and/or tool, that is brought into contact with the flex circuit (for example, conductive layer 110) during laser operation. Such tip, collet, feature, or tool preferably comprises an opening through which the laser beam is transmitted.

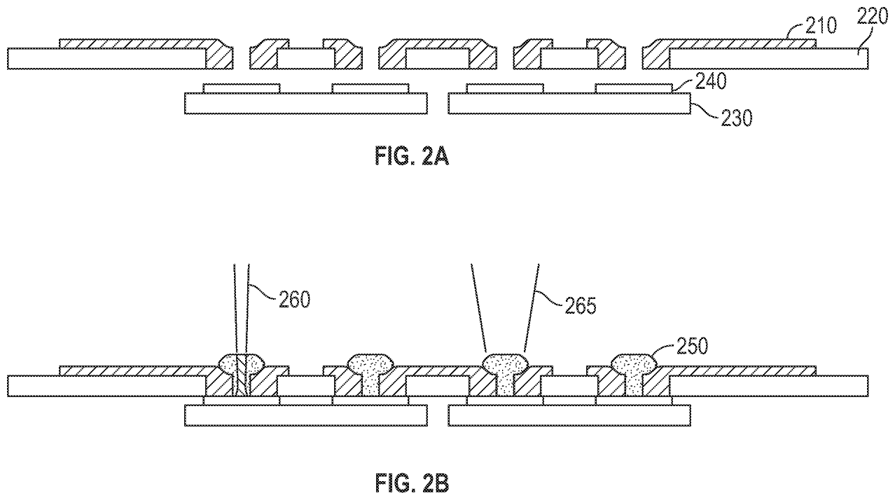

In another embodiment, shown in FIGS. 2A-2B, the interconnect structure, which comprises conductive layer 210 and insulating layer 220, comprises openings in certain locations, and the joining process is preferably performed by printing or depositing powder, ink or paste 250 into those openings, which have preferably been aligned with connection areas over connection pads 240 on solar cells 230. A laser beam is preferably used to melt and/or sinter in order to join interconnect structure 210 to connection pads 240. This can be performed by using small beams and multiple connection points, or by illuminating most of the connection area as described above, as shown by different size laser beams 260 and 265. The larger area processing can also be achieved by scanning the smaller laser beam 260 over the desired larger connection area while ensuring the energy deposited is at the desired level to form a uniform and reliable connection. This may be verified and indicated by the correct, void-free melting and joining pattern of the metals in the interconnect and connection pad regions.

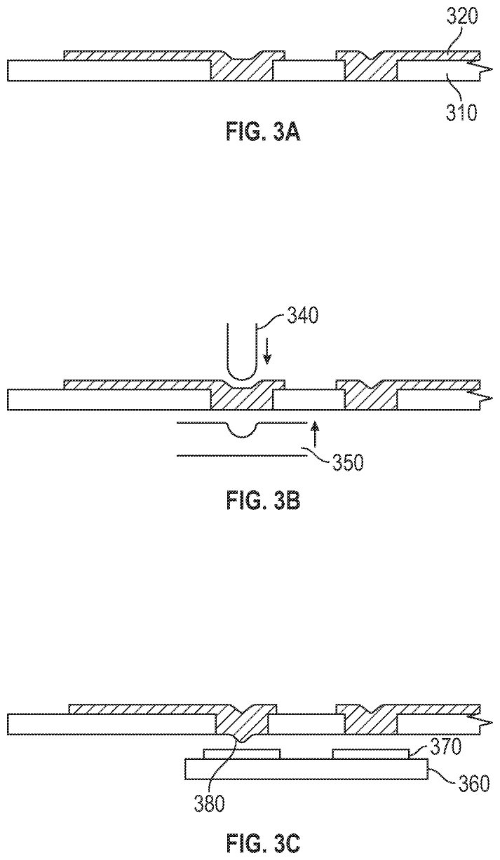

In other embodiments, to ensure close mechanical contact between the traces and the contact layer below before the laser welding/joining process, the copper trace contact locations can be shaped, for example in a downward facing semi-hemispherical form, and/or the contact layer below could be made in the shape of a raised bump. As shown in FIGS. 3A-30, this can be accomplished by mechanically deforming a previously formed connection point, for example a plated via, in an interconnect structure that comprises conductive layer 320 and insulating layer 310. In one embodiment, pin 340 is pushed into conductive layer 320 against optional underlying mold 350, which preferably comprises a matching indentation, thus forming the desired mechanical protrusion 380 which connects to connection pads 370 on cells 360, In another embodiment, a similar shape can be achieved by overplating the via and having a mushroom like region that protrudes further out from the interconnect surface. In yet another embodiment, the same mechanical feature can be formed by double-screen printing of a conductive ink or paste layer and curing it with temperature or by light (UV exposure or by laser beam). Prior to formation of protrusion 380, conductive layer 320 may be flat or comprise other topographies, such as the surface indentations shown in FIG. 3A, which may be formed, for example, during electroplating of conductive layer 320 over the openings in insulating layer 310, or using a tuned laser to form cuts or openings in insulating layer 310 without removing conductive layer 320.

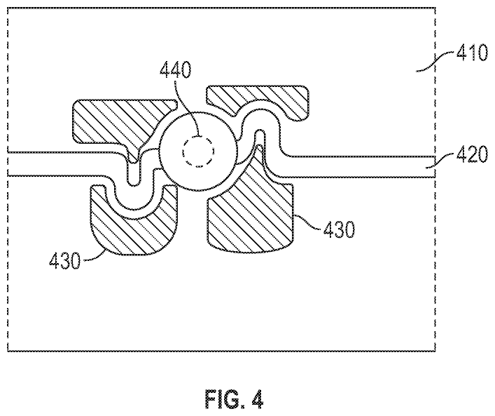

After formation of the weld or joint between the interconnect and the device, it is preferable to manage the mechanical stresses that may be experienced by this joint. To ensure good mechanical contact between the interconnect traces and the connection pad, a mechanically or otherwise shaped trace contact area is preferable. Similar to the above-mentioned out of plane shaping processes, additional design features can be added and forming processes may also be carried out in the planar dimensions (in-plane with the traces) with folded beam or bent beam traces that allow the traces to move and bend to accommodate any displacements or stresses that could be imposed on the structure, such as thermally driven or vibration/impact driven movements. To mitigate and potentially remove any reliability concerns due to mechanical stresses generated during fabrication or during operation of this structure, a shaped connection can be formed as shown in FIG. 4. Conductive traces 420 are deposited on insulating layer 410 (comprising for example polyimide), which comprises cutouts 430, both in a shape or configuration to provide movement and stress relief within the assembly that could be caused by coefficient of thermal expansion (CTE) differences among materials in the stack due to differences in temperature both during initial formation of the structure and during various operational conditions for the structure (for example, during full sun exposure where higher temperatures are reached and during eclipses in orbit where lower temperatures are reached for satellite applications). As described previously, an opening or mechanical protrusion 440 in the conductive traces can be used to form the desired connection between the interconnect layer and the underlying cells.

Mechanical stresses on the structure may also occur during handling and operation of this assembly. Especially in, but not limited to, those cases, mechanical support structures can be embedded into the assembly, either above or below the cells, that add further mechanical strength to the assembly. These could be above and/or below each individual cell or groups of cells, with flexible interconnects providing the electrical connections and desired mechanical flexibility to the assembly. The support structures can be made out of transparent layers such as polycarbonate, glass, acrylic and placed or embedded above (light input side) and/or below (back side) of the cell, which will allow bifacial operation of the photovoltaic system (accepting light input from both sides of the structure). In another configuration, where light input is blocked or otherwise not desired from the back side, opaque materials can be used for the support structure below the cells. These mechanical structures and grouping of cells are preferably independent from the desired electrical connections among the cells. For example, a support structure could be below two cells only, while electrically a larger number of cells, for example, five cells, could be interconnected without any interference from the mechanical grouping of the cells and support structures.

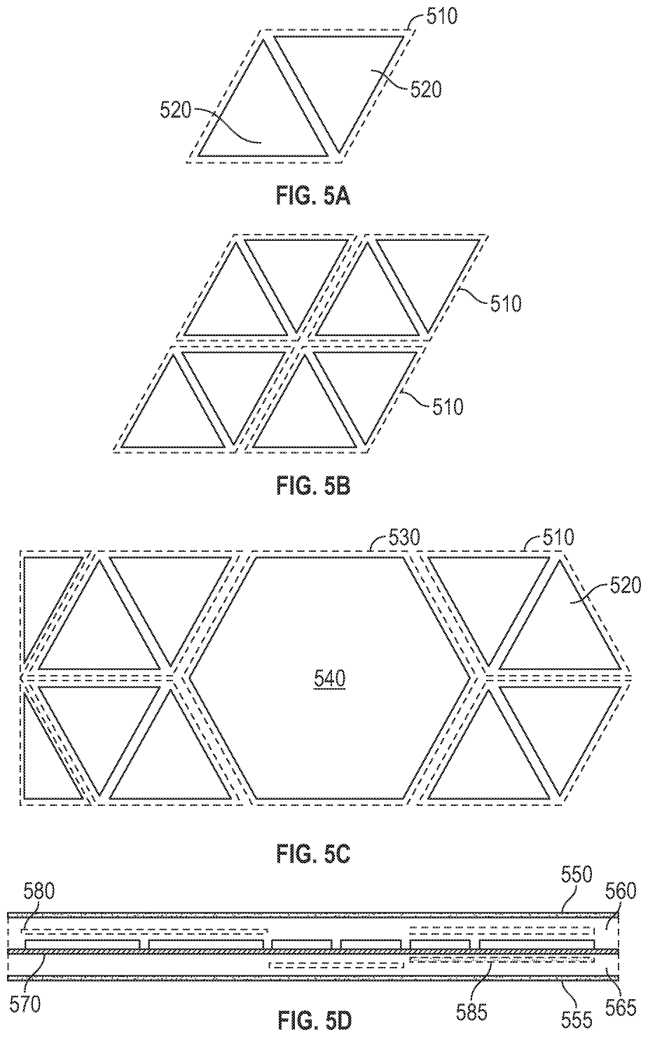

As shown in FIGS. 5A-5D, mechanical support structures can be embedded into the assembly to provide further mechanical resilience. These preferably comprise acrylic, glass and/or other transparent polymers, or opaque materials in locations where light transmission is not possible or not desired, Support structures can be shaped to cover each individual cell 520 or alternatively groups of cells, with varying shapes and sizes. For example, in FIGS. 5A-5C, mechanical support structure 510 covers two triangular cells 520, while mechanical support structure 530 covers only single hexagonal cell 540. The shape, size and placement of these support structures are preferably independent of the electrical interconnect among the solar cells, which can be optimized to provide electrical and mechanical resilience. For example, three triangular cells and one hexagonal cell could be interconnected electrically while they are supported by three different sized mechanical support structures. As shown in the cross-sectional schematic of FIG. 5D, one or more mechanical support structures 580 can be embedded into polymeric encapsulation layers 560, 565. Alternatively or in addition, one or more mechanical support structures 585 can be placed onto cell and interconnect assembly 570 or form an integral part of interconnect assembly 570, for example as stamped fiberglass/polymer composite elements in the insulating layer of the interconnect. Encapsulation layers are then added onto the structure. Front and back cover layers 550, 555 can be assembled or deposited onto encapsulation layers 560, 565 to provide additional mechanical protection or other functions such as anti-reflection (AR) or infrared reflection (IRR). Alternatively, the cover layers may be integrated onto the structure as a monolithic assembly, including the encapsulant, mechanical support structures and other components such as connectors.

Note that in the specification and claims, “about” or “approximately” means within twenty percent (20%) of the numerical amount cited. As used herein, the singular forms “a,” “an,” and “the” include plural referents unless the context clearly dictates otherwise. Thus, for example, reference to “a functional group” refers to one or more functional groups, and reference to “the method” includes reference to equivalent steps and methods that would be understood and appreciated by those skilled in the art, and so forth.

Although the invention has been described in detail with particular reference to the disclosed embodiments, other embodiments can achieve the same results. Variations and modifications of the present invention will be obvious to those skilled in the art and it is intended to cover all such modifications and equivalents. The entire disclosures of all patents and publications cited above are hereby incorporated by reference.

1. A photovoltaic assembly comprising:
a plurality of solar cells;
interconnects for interconnecting the solar cells; and
one or more mechanical support structures, the mechanical support structures each smaller than the photovoltaic assembly.

2. The photovoltaic assembly of claim 1 wherein the mechanical support structures comprise various shapes and sizes.

3. The photovoltaic assembly of claim 1 wherein at least one support structure is approximately the size of a single solar cell.

4. The photovoltaic assembly of claim 1 wherein at least one support structure is approximately the shape of a single solar cell.

5. The photovoltaic assembly of claim 1 wherein at least one mechanical support structure is approximately the size of a subset of the solar cells in the photovoltaic assembly.

6-7. (canceled)

8. The photovoltaic assembly of claim 1 wherein at least one mechanical support structure is approximately the shape of a subset of the solar cells in the photovoltaic assembly.

9-10. (canceled)

11. The photovoltaic assembly of any of claim 1 wherein at least one of the one or more mechanical support structures is transparent.

12. (canceled)

13. The photovoltaic assembly of claim 11 comprising transparent mechanical support structures disposed in a direction relative to the solar cells from which the solar cells receive light.

14. The photovoltaic assembly of claim 1 wherein the one or more mechanical support structures are oriented parallel to a plane of the solar cells.

15. The photovoltaic assembly of claim 1 wherein at least one mechanical support structure is embedded into a polymeric encapsulation layer.

16. The photovoltaic assembly of claim 1 wherein at least one mechanical support structure is disposed on a cell and interconnect assembly, the cell and interconnect assembly comprising a plurality of the solar cells and corresponding interconnects.

17-19. (canceled)

20. The photovoltaic assembly of claim 1 comprising a plurality of interconnect vias through an insulating layer.

21. The photovoltaic assembly of claim 20 wherein each via preferably comprises a protrusion to enhance contact with connection pads disposed on the solar cells.

22. The photovoltaic assembly of claim 1 wherein interconnect traces are shaped to reduce thermal stresses in the photovoltaic assembly.

23. The photovoltaic assembly of claim 22 wherein an insulating layer between the interconnect traces and the solar cells comprises cutouts that at least partially approximately conform to the shaped interconnect traces.

24. A method of manufacturing a photovoltaic assembly, the method comprising:
providing a plurality of solar cells and interconnects; and
disposing one or more mechanical support structures in the photovoltaic assembly, the mechanical support structures each smaller than the photovoltaic assembly.

25. (canceled)

26. The method of claim 24 wherein at least one support structure is approximately the size of a single solar cell.

27. The method of claim 24 wherein at least one support structure is approximately the shape of a single solar cell.

28. The method of claim 24 wherein at least one mechanical support structure is approximately the size of a subset of the solar cells in the photovoltaic assembly.

29-30. (canceled)

31. The method of claim 24 wherein at least one mechanical support structure is approximately the shape of a subset of the solar cells in the photovoltaic assembly.

32-33. (canceled)

34. The method of claim 24 wherein at least one of the one or more mechanical support structures is transparent.

35. (canceled)

36. The method of claim 34 comprising disposing the transparent mechanical support structures in a direction relative to the solar cells from which the solar cells receive light.

37. The method of claim 24 comprising orienting the one or more mechanical support structures parallel to a plane of the solar cells.

38-41. (canceled)

42. The method of claim 24 further comprising:
aligning a plurality of openings in the interconnects with connection pads disposed on the solar cells;
depositing material in the openings; and
using at least one laser beam to melt or sinter the material, thereby connecting the interconnects with the connection pads.

43. The method of claim 42 wherein the depositing step is performed using inject printing, screen printing, or aerosol jet nozzle printing.

44. The method of claim 42 wherein the material comprises powder, ink, paste, metal nanoparticles, copper, aluminum, transparent conductive oxides, indium tin oxide, polysilicon, silicided polysilicon, silver, titanium, or titanium-tungsten.

45. The method of claim 42 wherein a laser spot size is smaller than a size of the openings.

46. (canceled)

47. The method of claim 42 wherein a laser spot size is approximately the same as a size of the openings.

48. (canceled)

49. The method of claim 24 further comprising:
aligning interconnect vias through an insulating layer with connection pads disposed on the solar cells; and
using at least one laser beam to melt the interconnect vias, thereby connecting the interconnects to the contact pads.

50. The method of claim 49 wherein a laser spot size is smaller than a size of the openings.

51. The method of claim 50 further comprising scanning the laser beam within each opening.

52. The method of claim 49 wherein a laser spot size is approximately the same as a size of the openings.

53. (canceled)

54. The method of claim 24 comprising forming a plurality of interconnect vias through an insulating layer.

55-56. (canceled)

57. The method of claim 24 further comprising shaping interconnect traces to reduce thermal stresses in the photovoltaic assembly.

58. The method of claim 57 wherein an insulating layer between the interconnect traces and the solar cells comprises cutouts that at least partially approximately conform to the shaped interconnect traces.
